(19) United States
(12) Patent Application Publication
(10) Pub. No.: US 2021/0143247 A1
(43) Pub. Date: May 13, 2021

(54) DISPLAY PANEL, METHOD OF MANUFACTURING DISPLAY PANEL, AND DISPLAY APPARATUS

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Xinfeng Wu, Beijing (CN); Huihui Li, Beijing (CN); Fei Li, Beijing (CN); Xinzhu Wang, Beijing (CN); Youyuan Hu, Beijing (CN); Yanxian Wu, Beijing (CN); Chaoran Chen, Beijing (CN)

(21) Appl. No.: 16/824,842

(22) Filed: Mar. 20, 2020

(30) Foreign Application Priority Data
Nov. 13, 2019 (CN) 201911106130.2

(51) Int. Cl. H01L 27/32; H01L 51/52; H01L 51/56

(52) U.S. Cl. CPC H01L 27/3279; H01L 2227/323; H01L 51/56; H01L 51/524

(57) ABSTRACT

Embodiments of the present disclosure provide a display panel, a method of manufacturing the display panel, and a display apparatus. The display panel comprises: a display substrate and a packaging cover plate opposite to each other; a plurality of connection lines disposed at intervals on an edge of the display substrate; a plurality of insulating partitions on the display substrate, at least a portion of each of the insulating partitions being disposed between two adjacent ones of the connection lines, the display substrate, the packaging cover plate and every two adjacent ones of the insulating partitions defining an accommodation space together, and at least one of the connection lines being located in one of the accommodation spaces; and conductive fillers respectively filled in the accommodation spaces, and each covering at least a portion of a surface of a corresponding one of the connection lines.

### CROSS-REFERENCE TO RELATED APPLICATION

This application claims priority to Chinese Patent Application No. 201911106130.2, filed on Nov. 13, 2019, entitled “DISPLAY PANEL, METHOD OF MANUFACTURING DISPLAY PANEL, AND DISPLAY APPARATUS”, which is incorporated herein by reference in its entirety.

### TECHNICAL FIELD

Embodiments of the present disclosure relate to the field of display technology, and particularly to a display panel, a method of manufacturing the display panel, and a display apparatus.

### BACKGROUND

At present, in order to reduce a frame of a display panel, generally, a COF (chip on flexible printed board or chip on film) is bonded (i.e. side-bonded) to a side of lines exposed on an edge of the display panel, which can greatly reduce a size of the frame and thus is beneficial to realize the narrow frame of the display panel.

### SUMMARY

In an aspect of the present disclosure, embodiments of the present disclosure provide a display panel comprising: a display substrate and a packaging cover plate disposed opposite to each other; a plurality of connection lines disposed at intervals on an edge of the display substrate; a plurality of insulating partitions disposed on the display substrate, at least a portion of each of the plurality of insulating partitions being disposed between two adjacent ones of the plurality of connection lines, the display substrate, the packaging cover plate and every two adjacent ones of the plurality of insulating partitions defining an accommodation space together, and at least one of the plurality of connection lines being located in one of the accommodation spaces; and conductive fillers respectively filled in the accommodation spaces, and each covering at least a portion of a surface of a corresponding one of the plurality of connection lines.

According to embodiments of the present disclosure, the accommodation spaces are fully filled with the conductive fillers, respectively.

According to embodiments of the present disclosure, a sum of an area of each of first end surfaces, facing towards an outside of the display panel, of the conductive fillers, and an area of each of second end surfaces, facing towards the outside of the display panel, of the connection lines is greater than or equal to 16 μm².

According to embodiments of the present disclosure, the first end surfaces are flush with the second end surfaces.

According to embodiments of the present disclosure, a contact area between each of the connection lines and a corresponding one of the conductive fillers is greater than or equal to 16 μm².

According to embodiments of the present disclosure, there is a gap between each of the connection lines and at least one of the insulating partitions adjacent to the each of the connection lines, and a portion of a corresponding one of the conductive fillers is filled in the gap.

According to embodiments of the present disclosure, the gap has a width of 0 μm to 3 μm.

According to embodiments of the present disclosure, the display panel further comprises: electrodes disposed on a side surface, facing towards the outside, of the display panel, and electrically connected to first end surfaces, facing towards the outside of the display panel, of the conductive fillers, and second end surfaces, facing towards the outside of the display panel, of the connection lines, respectively; and a COF disposed on a side of the electrodes facing away from the connection lines.

According to embodiments of the present disclosure, each of the electrodes and a corresponding one of the conductive fillers are disposed in an integrated structure.

According to embodiments of the present disclosure, each of the connection lines has a body, and an end connected to the body and having an outer peripheral surface around a center line of the end, the outer peripheral surface has a first outer peripheral surface portion facing towards the display substrate and a remaining second outer peripheral surface portion, and each of the conductive fillers covers at least a part of the second outer peripheral surface portion of the outer peripheral surface of the end of a corresponding one of the connection lines.

According to embodiments of the present disclosure, the display panel further comprises: an insulating layer covering the body of each of the plurality of the connection lines and exposing at least the part of the second outer peripheral surface portion of the outer peripheral surface of the end of each of the connection lines, wherein each of the plurality of insulating partitions is constituted by a portion of the insulating layer located between two adjacent ones of the plurality of connection lines in an arrangement direction of the plurality of connection lines.

According to embodiments of the present disclosure, the part of the second outer peripheral surface portion of the outer peripheral surface of the end of each of the connection lines comprises a surface facing towards the packaging cover plate.

In another aspect of the present disclosure, embodiments of the present disclosure provide a method of manufacturing a display panel. According to embodiments of the present disclosure, the method comprises: providing a display substrate, a plurality of connection lines being disposed at intervals on an edge of the display substrate; forming an insulating layer on a surface of the edge, the insulating layer covering the plurality of connection lines and gaps between adjacent ones of the plurality of connection lines; removing a portion of the insulating layer on at least a portion of a surface of each of the connection lines to form a plurality of insulating partitions; placing a packaging cover plate on a surface of the display substrate, the packaging cover plate covering the plurality of insulating partitions, the display substrate, the packaging cover plate and every two adjacent ones of the plurality of insulating partitions defining an accommodation space together, and at least one of the plurality of connection lines being located in one of the accommodation spaces; and filling conductive fillers in the accommodation spaces, respectively, each of the conductive fillers covering at least a portion of a surface of a corresponding one of the plurality of connection lines.

According to embodiments of the present disclosure, the method further comprises: forming electrodes on first end surfaces, facing towards an outside of the display panel, of the conductive fillers, and on second end surfaces, facing towards the outside of the display panel, of the connection lines; and bonding a COF to a side of the electrodes facing away from the connection lines.

According to embodiments of the present disclosure, each of the electrodes and a corresponding one of the conductive fillers are integrally formed.

According to embodiments of the present disclosure, the conductive fillers and the electrodes are formed by screen printing or printing.

According to embodiments of the present disclosure, each of the connection lines has a body, and an end connected to the body and having an outer peripheral surface around a center line of the end, the outer peripheral surface has a first outer peripheral surface portion facing towards the display substrate and a remaining second outer peripheral surface portion, and each of the conductive fillers covers at least a part of the second outer peripheral surface portion of the outer peripheral surface of the end of a corresponding one of the connection lines.

According to embodiments of the present disclosure, removing the portion of the insulating layer comprises: removing a portion of the insulating layer covering at least the part of the second outer peripheral surface portion of the outer peripheral surface of the end of each of the connection lines, while retaining a portion of the insulating layer covering the body of each of the connection lines, so as to expose at least the part of the second outer peripheral surface portion of the outer peripheral surface of the end of each of the connection lines, wherein each of the plurality of insulating partitions is constituted by a portion of the insulating layer located between two adjacent ones of the plurality of connection lines in an arrangement direction of the plurality of connection lines.

According to embodiments of the present disclosure, the part of the second outer peripheral surface portion of the outer peripheral surface of the end of each of the connection lines comprises a surface facing towards the packaging cover plate.

In still another aspect of the present disclosure, embodiments of the present disclosure provide a display apparatus. According to embodiments of the present disclosure, the display apparatus comprises the above display panel.

### BRIEF DESCRIPTION OF THE DRAWINGS

FIG. 1 is a schematic sectional view showing a structure of a display panel without conductive fillers filled in accommodation spaces according to an embodiment of the present disclosure.

FIG. 2 is a schematic perspective view showing the structure of the display panel without the conductive fillers filled in the accommodation spaces according to the embodiment of the present disclosure.

FIG. 3 is a schematic sectional view showing the structure of the display panel with the conductive fillers filled in the accommodation spaces according to the embodiment of the present disclosure.

FIG. 4 is a schematic perspective view showing the structure of the display panel with the conductive fillers filled in the accommodation spaces according to the embodiment of the present disclosure.

FIG. 5 is a schematic perspective view showing a structure of a display panel without conductive fillers filled in accommodation spaces according to a further embodiment of the present disclosure.

FIG. 6 is a schematic perspective view showing the structure of the display panel with the conductive fillers filled in the accommodation spaces according to the further embodiment of the present disclosure.

FIG. 7 is a schematic sectional view showing the structure of the display panel with the conductive fillers filled in the accommodation spaces according to the further embodiment of the present disclosure.

FIG. 8 is a schematic perspective view showing a structure of a display panel without conductive fillers filled in accommodation spaces according to a still further embodiment of the present disclosure.

FIG. 9 is a schematic sectional view showing a structure of a display panel formed with a bonding electrode to which a COF is connected, according to an embodiment of the present disclosure.

FIG. 10 is a schematic sectional view showing the structure of the display panel, which is taken along the line CC′ in FIG. 9.

FIG. 11 is a flow diagram showing a method of manufacturing a display panel according to an embodiment of the present disclosure.

FIG. 12 is a flow diagram showing a method of manufacturing a display panel according to another embodiment of the present disclosure.

### DETAILED DESCRIPTION

Embodiments of the present disclosure will be described as follows in detail. The embodiments described below are exemplary, are only used to explain the present disclosure, and should not be construed to limit the present disclosure. The specific technology or condition that is not indicated in the embodiments conforms to the technology or condition described in literatures in the art or the product specification.

At present, in order to achieve a narrow frame of a display panel, generally a COF (chip on flexible printed board or chip on film) is side-bonded. A specific process includes: firstly applying an insulating adhesive on an edge of a display panel so as to smooth an uneven surface of the edge of the display panel caused by connection lines on the edge of the display panel, then grinding the surface of the edge of the display panel, after that forming, by screen printing or printing, metal electrodes in contact with and connected to end surfaces of the connection lines, on the surface of the edge of the display panel, and finally bonding the COF to surfaces of the metal electrodes. However, the inventors found that although the above process can effectively reduce the frame of the display panel, the display effect is poor. The inventors found that in the above bonding process, a bonding area between the COF and the connection line (that is, a contact area between the metal electrode and the connection line) is small, and thus an impedance between them is large, which seriously affects the electric conductivity, resulting in a poor display effect. In view of the above problem, the inventors found through in-depth research that conductive filler in contact with the connection line can be filled to increase a connection area of the bonded COF and reduce the impedance, effectively improving the display effect of the display panel.

In view of this, in an aspect of the present disclosure, embodiments of the present disclosure provide a display panel. According to embodiments of the present disclosure, referring to FIG. 1 (in which conductive fillers 50 are not illustrated), FIG. 2 (in which a packaging cover plate 20 and the conductive fillers 50 are not illustrated, and which is a schematic view showing a structure corresponding to one of connection lines shown in FIG. 1), and FIG. 3, the display panel comprises a display substrate 10 and a packaging cover plate 20 disposed opposite to each other. A plurality of connection lines 30 are disposed at intervals on an edge of the display substrate 10. The display panel further comprises: a plurality of insulating partitions 40 disposed on the display substrate 10, at least a portion of each of the plurality of insulating partitions 40 being disposed between two adjacent ones of the plurality of connection lines 30, the display substrate 10, the packaging cover plate 20 and every two adjacent ones of the plurality of insulating partitions 40 defining an accommodation space 124 together, and at least one of the plurality of connection lines 30 being located in one of the accommodation spaces 124; and conductive fillers 50 respectively filled in the accommodation spaces 124, and each covering at least a portion of a surface of a corresponding one of the plurality of connection lines 30. Thereby, the conductive fillers respectively covering the plurality of connection lines are filled in the accommodation spaces, respectively. Therefore, a bonding area of the COF (comprising a bonding area between the COF and the connection line and a bonding area between the COF and the conductive filler) can be increased when the COF is bonded. As a result, an impedance is decreased so that the electric conductivity is good, improving a display effect of the display panel.

According to embodiments of the present disclosure, the accommodation space 124 is defined by the display substrate 10, the packaging cover plate 20 and every two adjacent ones of the plurality of insulating partitions 40 together. In other words, as shown in FIG. 3, the packaging cover plate covers the plurality of insulating partitions, or an orthogonal projection of the packaging cover plate on the display substrate covers orthogonal projections of the plurality of insulating partitions on the display substrate.

It would be appreciated by those skilled in the art that the connection lines extend from a display region of the display panel to the edge of the display panel, and the COF is bonded to the connection lines to be electrically connected to a drive circuit in the display region. There are no particular requirements for a material for forming the connection lines, a dimension of the connection lines, and a distance between two adjacent ones of the connection lines. Those skilled in the art could flexibly choose according to actual conditions such as a size and a resolution of a product.

According to embodiments of the present disclosure, a specific structure of the display substrate is consistent with that of a conventional display substrate. The display substrate comprises structures such as a thin film transistor, an OLED, and an encapsulation layer. Those skilled in the art could flexibly select a display substrate of a conventional structure according to actual needs. In addition, there is also no limitation on a material of the packaging cover plate. Those skilled in the art could flexibly choose according to actual conditions.

According to embodiments of the present disclosure, there is also no particular limitation on a material of the insulating partitions. Those skilled in the art could flexibly choose according to actual conditions. In some embodiments, the material of the insulating partitions comprises, but is not limited to, materials such as silicon oxide, silicon oxynitride, silicon nitride, and aluminum oxide. Therefore, the above materials have a wide range of sources, low cost, and good stability, and can maintain good insulating property in different environments for a long time to prevent an electric connection with the connection lines.

According to embodiments of the present disclosure, there are also no particular requirements for a specific material of the conductive fillers. Those skilled in the art could flexibly choose according to actual conditions. For example, the specific material of the conductive fillers comprises, but is not limited to, conductive materials such as silver adhesive or paste, copper, and aluminum. Thereby, the electric conductivity is good and the cost is low.

According to embodiments of the present disclosure, referring to FIG. 4, the accommodation spaces are fully filled with the conductive fillers 50, respectively. Thereby, a contact area between the connection line and the conductive filler and an area of a first end surface, facing towards an outside of the display panel, of the conductive filler can be further increased, thereby effectively increasing the electric conductivity between the bonded COF and the connection lines, reducing the impedance between them, and improving the display quality of the display panel.

According to embodiments of the present disclosure, referring to FIG. 4, a sum of an area of each of first end surfaces 51, facing towards an outside of the display panel, of the conductive fillers 50, and an area of each of second end surfaces 31, facing towards the outside of the display panel, of the connection lines 30 is greater than or equal to 16 μm. For example, the sum is 16 μm², 17 μm², 18 μm², 19 μm², 20 μm², 21 μm², 22 μm², 23 μm², 24 μm², 25 μm², 26 μm², 27 μm², 28 μm², 29 μm², 30 μm², 31 μm², 32 μm², 33 μm², 34 μm², 35 μm², 36 μm², 37 μm², 38 μm², 39 μm² or 40 μm². Therefore, the areas of the first end surface and the second end surface are relatively large, the bonding area of the COF can be effectively increased, the impedance can be decreased, and the electric conductivity is increased, thereby improving the display effect of the display panel. If the areas of the first end surface and the second end surface are less than 16 μm², the bonding area is relatively small, resulting in relatively insufficient electric conductivity, and the display effect of the display panel is not significantly improved.

Those skilled in the art could flexibly design dimensions of the insulating partition such as a height of the insulating partition according to actual conditions such as the area of the second end surface of the connection line and requirements on a size of the binding area. In some embodiments, referring to FIG. 1, assuming that a width H of the connection line is 14 μm and a thickness S of the connection line is 0.6 μm, a minimum value A of a height (or thickness) D of the insulating partition is given by A=16/14=1.14 μm. In other words, the thickness of the insulating partition is at least 0.54 μm greater than the thickness of the connection line. After the conductive filler is filled in the accommodation space, the area of the end surface, facing the outside of the display panel, of the conductive filler is at least 0.54 μm*14 μm=7.56 μm². In this way, the sum of the area of each of the first end surfaces, facing towards the outside of the display panel, of the conductive fillers, and the area of each of the second end surfaces, facing towards the outside of the display panel, of the connection lines meets the requirement that it is greater than or equal to 16 μm², and the impedance can be reduced by about 50 percent. It is to be noted that in the embodiment, the insulating partition and the connection line are compactly disposed with no gap between them. In other words, a width of the connection line and a width of the conductive filler are the same.

According to embodiments of the present disclosure, referring to FIG. 4, the first end surfaces 51, facing towards the outside of the display panel, of the conductive fillers 50 are flush with the second end surfaces 31, facing towards the outside of the display panel, of the connection lines 30. Thereby, the smooth surface facilitates a side bonding of the COF to the connection lines and the conductive fillers, and a stability of the bonded COF.

In some embodiments, in the case where the first end surfaces are not flush with the second end surfaces, the electrodes or bonding electrodes may be formed by a silver paste to smooth an uneven surface formed by the second end surfaces of the connection lines and the first end surfaces of the conductive fillers, thereby facilitating the side binding of the COF. Furthermore, the sliver paste as a conductive material may be filled in the accommodation spaces, and form the electrodes. In other words, the conductive fillers and the electrodes are formed by the silver paste in a single process to obtain the electrodes having smooth surfaces, thereby facilitating the side binding of the COF.

According to embodiments of the present disclosure, in order to improve the display effect of the display panel better, a contact area between each of the connection lines and a corresponding one of the conductive fillers is greater than or equal to 16 μm². For example, the contact area is 16 μm², 17 μm², 18 μm², 19 μm², 20 μm², 21 μm², 22 μm², 23 μm², 24 μm², 25 μm², 26 μm², 27 μm², 28 μm², 29 μm², 30 μm², 31 μm², 32 μm², 33 μm², 34 μm², 35 μm², 36 μm², 37 μm², 38 μm², 39 μm² or 40 μm². Thereby, the impedance between the connection line and the conductive filler is relatively small and the electric conductivity between the connection line and the conductive filler is good, thereby effectively ensuring the electric conductivity of the circuit after the COF is bonded and thus effectively improving the display effect of the display panel.

Those skilled in the art could design dimensions of the conductive filler such as a filling depth according to actual conditions such as requirements for a size of the contact area between the connection line and the conductive filler, and dimensions of the connection line. In some embodiments, referring to FIGS. 3 and 4, assuming that the width of the connection line 30 is 14 μm and the thickness of the connection line is 0.6 μm, a minimum value B of the filling depth h of the conductive filler 50 is given by B=16/14=1.14 μm. It is to be noted that in the embodiment, the insulating partition and the connection line are compactly disposed with no gap between them. In other words, a width of the connection line and a width of the conductive filler are the same.

According to embodiments of the present disclosure, referring to FIGS. 5, 6 and 7, there is a gap 34 between each of the connection lines 30 and at least one of the insulating partitions 40 adjacent to the each of the connection lines 30, and a portion of a corresponding one of the conductive fillers 50 is filled in the gap 34. Thereby, the conductive filler is in contact with and connected to not only an upper surface of the connection line, but also at least one side surface of the connection line. In this way, the contact area between the connection line and the conductive filler can be further increased, the impedance between the connection line and the conductive filler can be further decreased, and the electric conductivity between the connection line and the conductive filler can be further increased, thereby improving a display quality of the display panel.

According to embodiments of the present disclosure, as shown in FIGS. 5-7, there is a gap 34 between the connection line 30 and each of two insulating partitions 40 on both sides of the connection line 30, or as shown in FIG. 8, there may also be a gap 34 between the connection line 30 and one of the insulating partitions 40 on both sides of the connection line 30 (that is, there is no gap between the connection line 30 and the other of the insulating partitions 40 on both sides of the connection line 30). There is no particular limitation on the gap herein. Those skilled in the art could flexibly design the gap according to actual conditions such as requirements for the contact area between the connection line and the conductive fill.

According to embodiments of the present disclosure, the gap has a width d of 0 pm to 3 pm. For example, the width of the gap is 3 μm, 2.8 μm, 2.5 μm, 2.3 μm, 2.0 μm, 1.8 μm, 1.5 μm, 1.2 μm, 1.0 μm, 0.8 μm, 0.5 μm, 0.3 μm, or 0.1 μm. Therefore, the contact area between the connection line and the conductive filler is increased, and at the same time a structural stability of the insulating partition is effectively guaranteed.

According to embodiments of the present disclosure, referring to FIGS. 2, 4-6 and 8, each of the connection lines 30 has a body, and an end 301 connected to the body and having an outer peripheral surface 302 around a center line of the end 301, the outer peripheral surface 302 has a first outer peripheral surface portion facing towards the display substrate and the remaining second outer peripheral surface portion, and each of the conductive fillers 50 covers at least a part of the second outer peripheral surface portion of the outer peripheral surface 302 of the end 301 of a corresponding one of the connection lines 30.

According to embodiments of the present disclosure, referring to FIGS. 2, 4-6 and 8, the display panel further comprises: an insulating layer 4 covering the body of each of the plurality of the connection lines 30 and exposing at least the part of the second outer peripheral surface portion of the outer peripheral surface 302 of the end 301 of each of the connection lines 30. Each of the plurality of insulating partitions 40 is constituted by a portion of the insulating layer 4 located between two adjacent ones of the plurality of connection lines 30 in an arrangement direction of the plurality of connection lines 30. The part of the second outer peripheral surface portion of the outer peripheral surface 302 of the end 301 of each of the connection lines 30 comprises a surface facing towards the packaging cover plate.

According to embodiments of the present disclosure, referring to FIGS. 9 and 10 (FIG. 10 is a schematic sectional view of the display panel, which is taken along the line CC′ in FIG. 9), the display panel further comprises: electrodes 60 disposed on a side surface, facing towards the outside, of the display panel, and electrically connected to end surfaces (first end surfaces), facing towards the outside of the display panel, of the conductive fillers 50, and end surfaces (second end surfaces), facing towards the outside of the display panel, of the connection lines 30, respectively; and a COF 70 disposed on a side of the electrodes 60 facing away from the connection lines 30.

Thereby, the COF 70 is bonded through the electrodes to the end surfaces, facing towards the outside of the display panel, of the connection lines 30 and the end surfaces, facing towards the outside of the display panel, of the conductive fillers 50, thereby increasing the bonding area and thus improving the display effect of the display panel. It is to be noted that the bonding area of the COF is a sum of an area where the electrode 60 is in contact with and connected to the end surface, facing towards the outside of the display panel, of the connection line 30 and an area where the electrode 60 is in contact with and connected to the end surface, facing towards the outside of the display panel, of the conductive filler 50.

According to embodiments of the present disclosure, each of the electrodes and a corresponding one of the conductive fillers are disposed in an integrated structure. Thereby, not only a manufacture of the electrodes and the conductive fillers is facilitated in technology, but a connectional stability between the electrode and the conductive filler is also good. It is to be noted that “each of the electrodes and a corresponding one of the conductive fillers are disposed in an integrated structure” means that each of the electrodes and the corresponding one of the conductive fillers are integrally formed in a process, which indicates that the electrodes and the conductive fillers are formed of the same material.

In another aspect of the present disclosure, embodiments of the present disclosure provide a method of manufacturing a display panel. According to embodiments of the present disclosure, referring to FIG. 11, the method comprises the following steps.

In a step S100, a display substrate is provided. A plurality of connection lines are disposed at intervals on an edge of the display substrate.

In a step S200, an insulating layer is formed on a surface of the edge. The insulating layer covers the plurality of connection lines and gaps between adjacent ones of the plurality of connection lines. There is no particular requirement on a method of forming the insulating layer, and those skilled in the art could flexibly choose according to actual conditions. For example, the method of forming the insulating layer includes, but is not limited to, coating, deposition, and the like.

In a step S300, a portion of the insulating layer on at least a portion of a surface of each of the connection lines 30 is removed to form a plurality of insulating partitions 40, referring to FIG. 2.

There is also no limitation on a specific method of removing the portion of the insulating layer on at least the portion of the surface of each of the connection lines. For example, the portion of the insulating layer may be removed by an exposure and a development. Those skilled in the art could flexibly choose according to actual needs, and the specific method is no longer described herein for the sake of brevity.

In a step S400, a packaging cover plate 20 is placed on a surface of the display substrate 10. The packaging cover plate 20 covers the plurality of insulating partitions 40. The display substrate 10, the packaging cover plate 20 and every two adjacent ones of the plurality of insulating partitions 40 define an accommodation space 124 together, and at least one of the plurality of connection lines 30 is located in one of the accommodation spaces 124, referring to FIG. 1.

In a step S500, conductive fillers 50 are filled in the accommodation spaces 124, respectively. Each of the conductive fillers 50 covers at least a portion of a surface of a corresponding one of the plurality of connection lines 30, referring to

FIGS. 3 and 4.

According to embodiments of the present disclosure, referring to FIG. 4, a sum of an area of each of first end surfaces 51, facing towards an outside of the display panel, of the conductive fillers 50, and an area of each of second end surfaces 31, facing towards the outside of the display panel, of the connection lines 30 is greater than or equal to 16 μm². For example, the sum is 16 μm², 17 μm², 18 μm², 19 μm², 20 μm², 21 μm², 22 μm², 23 μm², 24 μm², 25 μm², 26 μm², 27 μm², 28 μm², 29 μm², 30 μm², 31 μm², 32 μm², 33 μm², 34 μm², 35 μm², 36 μm², 37 μm², 38 μm², 39 μm² or 40 μm².

Thereby, the bonding area of the COF is relatively large, effectively reducing the impedance, increasing the electric conductivity, and thus improving the display effect of the display panel. If the bonding area is less than 16 μm², the electric conductivity is relatively insufficient, and the display effect of the display panel is not significantly improved.

According to embodiments of the present disclosure, referring to FIG. 4, the first end surfaces 51, facing towards the outside of the display panel, of the conductive fillers 50 are flush with the second end surfaces 31, facing towards the outside of the display panel, of the connection lines 30. Thereby, the smooth surface facilitates a side bonding of the COF to the connection lines and the conductive fillers, and a stability of the bonded COF.

According to embodiments of the present disclosure, in order to improve the display effect of the display panel better, a contact area between each of the connection lines and a corresponding one of the conductive fillers is greater than or equal to 16 μm². For example, the contact area is 16 μm², 17 μm², 18 μm², 19 μm², 20 μm², 21 μm², 22 μm², 23 μm², 24 μm², 25 μm², 26 μm², 27 μm², 28 μm², 29 μm², 30 μm², 31 μm², 32 μm², 33 μm², 34 μm², 35 μm², 36 μm², 37 μm², 38 μm², 39 μm² or 40 μm². Thereby, the impedance between the connection line and the conductive filler is relatively small and the electric conductivity between the connection line and the conductive filler is good, thereby effectively ensuring the electric conductivity of the circuit after the COF is bonded and thus effectively improving the display effect of the display panel.

According to embodiments of the present disclosure, the conductive fillers respectively covering the plurality of connection lines are filled in the accommodation spaces, respectively. Therefore, a bonding area of the COF (comprising a bonding area between the COF and the connection line and a bonding area between the COF and the conductive filler) can be increased when the COF is bonded. As a result, an impedance is decreased so that the electric conductivity is good, improving a display effect of the display panel. Furthermore, the manufacturing method is simple and mature in technology, is easy to operate, has a high efficiency, and is convenient for industrial production.

According to embodiments of the present disclosure, referring to FIG. 12, the method further comprises:

a step S600 of forming electrodes 60 on first end surfaces, facing towards an outside of the display panel, of the conductive fillers 50, and second end surfaces, facing towards the outside of the display panel, of the connection lines 30, referring to FIG. 10.

Each of the electrodes 60 and a corresponding one of the conductive fillers 50 are integrally formed. Thereby, not only a manufacture of the electrodes and the conductive fillers is facilitated in technology, but a connectional stability between the electrode and the conductive filler is also good.

According to embodiments of the present disclosure, the conductive fillers and the electrodes are formed by screen printing or printing. Thereby, the method is not only mature in technology, easy to operate, and convenient for industrial production, but by the method, the conductive filler can also be effectively and quickly filled into the accommodation space.

In a step S700, a COF 70 is bonded to a side of the electrodes 60 facing away from the connection lines 30, referring to FIG. 10.

There is no particular limitation on a specific method of bonding the COF. Those skilled in the art could flexibly choose according to actual conditions, and the specific method is no longer described herein for the sake of brevity.

According to embodiments of the present disclosure, referring to FIGS. 2, 4-6 and 8, each of the connection lines 30 has a body, and an end 301 connected to the body and having an outer peripheral surface 302 around a center line of the end 301, the outer peripheral surface 302 has a first outer peripheral surface portion facing towards the display substrate and the remaining second outer peripheral surface portion, and each of the conductive fillers 50 covers at least a part of the second outer peripheral surface portion of the outer peripheral surface 302 of the end 301 of a corresponding one of the connection lines 30.

According to embodiments of the present disclosure, referring to FIGS. 2, 4-6 and 8, the step S300 comprises: removing a portion of the insulating layer 4 covering at least the part of the second outer peripheral surface portion of the outer peripheral surface 302 of the end 301 of each of the connection lines 30, while retaining a portion of the insulating layer 4 covering the body of each of the connection lines 30, so as to expose at least the part of the second outer peripheral surface portion of the outer peripheral surface 302 of the end 301 of each of the connection lines 30. Each of the plurality of insulating partitions 40 is constituted by a portion of the insulating layer 4 located between two adjacent ones of the plurality of connection lines 30 in an arrangement direction of the plurality of connection lines 30. The part of the second outer peripheral surface portion of the outer peripheral surface 302 of the end 301 of each of the connection lines 30 comprises a surface facing towards the packaging cover plate.

According to embodiments of the present disclosure, the method may be used to manufacture the above display panel. Requirements for the material of the conductive fillers, the material of the electrodes, the contact area between the conductive filler and the connection line, the bonding area, and the like in the method are the same as the requirements for the corresponding structures in the above display panel, and are no longer described one by one herein for the sake of brevity.

In still another aspect of the present disclosure, embodiments of the present disclosure provide a display apparatus. According to embodiments of the present disclosure, the display apparatus comprises the above display panel. Thereby, the display apparatus has a good display effect. It would be appreciated by those skilled in the art that the display apparatus has all the features and advantages of the above display panel, which are no longer described herein for the sake of brevity.

The display apparatus may comprise any products or parts having a displaying function, such as a mobile phone, a tablet computer, a TV, a display, a notebook computer, a digital frame, and a navigator.

According to embodiments of the present disclosure, there are no particular requirements for specific types of the display apparatus. Those skilled in the art could flexibly choose according to actual conditions. In some embodiments, the specific types of the display apparatus include, but are not limited to, all apparatuses or devices with a display function, such as a mobile phone, a notebook, an iPad, and a game console.

Those skilled in the art could understand that in addition to the display panel, the display apparatus further comprises structures or components necessary for a conventional display apparatus. Taking a mobile phone as an example, in addition to the display panel, the mobile phone further includes structures or components such as a touch panel, an audio module a camera module, a CPU, and a fingerprint identification module.

In the description of the present specification, the description with reference to the term “an embodiment”, “some embodiments”, “an example”, “specific example”, “some examples” or the like means that a specific feature, structure, material or characteristic described in conjunction with the embodiment or example is included in at least one embodiment or example of the present disclosure. In the present specification, the illustrative references to the above terms are not necessarily directed to the same embodiment or example. Furthermore the described specific features, structures, materials or characteristics may be combined in appropriate manners in any one or more embodiments or examples. In addition, those skilled in the art could combine the different embodiments or examples and the features of the different embodiments or examples described in the description unless they conflict.

While the embodiments of the present disclosure have been shown and described above, it will be appreciated that the above embodiments are illustrative and should not be construed as limiting the prevent disclosure. Those skilled in the art may make changes, modifications, substitutions and alterations to the above embodiments within the scope of the present disclosure.

What is claimed is:

1. A display panel comprising:
a display substrate and a packaging cover plate disposed opposite to each other;
a plurality of connection lines disposed at intervals on an edge of the display substrate;
a plurality of insulating partitions disposed on the display substrate, at least a portion of each of the plurality of insulating partitions being disposed between two adjacent ones of the plurality of connection lines, the display substrate, the packaging cover plate and every two adjacent ones of the plurality of insulating partitions defining an accommodation space together, and at least one of the plurality of connection lines being located in one of the accommodation spaces; and
conductive fillers respectively filled in the accommodation spaces, and each covering at least a portion of a surface of a corresponding one of the plurality of connection lines.

2. The display panel of claim 1, wherein:
the accommodation spaces are fully filled with the conductive fillers, respectively.

3. The display panel of claim 1, wherein:
a sum of an area of each of first end surfaces, facing towards an outside of the display panel, of the conductive fillers, and an area of each of second end surfaces, facing towards the outside of the display panel, of the connection lines is greater than or equal to 16 μm².

4. The display panel of claim 3, wherein:
the first end surfaces are flush with the second end surfaces.

5. The display panel of claim 1, wherein:
a contact area between each of the connection lines and a corresponding one of the conductive fillers is greater than or equal to 16 μm².

6. The display panel of claim 1, wherein:
there is a gap between each of the connection lines and at least one of the insulating partitions adjacent to the each of the connection lines, and a portion of a corresponding one of the conductive fillers is filled in the gap.

7. The display panel of claim 6, wherein:
the gap has a width of 0 μm to 3 μm.

8. The display panel of claim 1, further comprising:
electrodes disposed on a side surface, facing towards the outside, of the display panel, and electrically connected to first end surfaces, facing towards the outside of the display panel, of the conductive fillers, and second end surfaces, facing towards the outside of the display panel, of the connection lines, respectively; and
a COF disposed on a side of the electrodes facing away from the connection lines.

9. The display panel of claim 8, wherein:
each of the electrodes and a corresponding one of the conductive fillers are disposed in an integrated structure.

10. The display panel of claim 1, wherein:
each of the connection lines has a body, and an end connected to the body and having an outer peripheral surface around a center line of the end, the outer peripheral surface has a first outer peripheral surface portion facing towards the display substrate and a remaining second outer peripheral surface portion, and each of the conductive fillers covers at least a part of the second outer peripheral surface portion of the outer peripheral surface of the end of a corresponding one of the connection lines.

11. The display panel of claim 10, further comprising:
an insulating layer covering the body of each of the plurality of the connection lines and exposing at least the part of the second outer peripheral surface portion of the outer peripheral surface of the end of each of the connection lines, wherein each of the plurality of insulating partitions is constituted by a portion of the insulating layer located between two adjacent ones of the plurality of connection lines in an arrangement direction of the plurality of connection lines.

12. The display panel of claim 10, wherein:
the part of the second outer peripheral surface portion of the outer peripheral surface of the end of each of the connection lines comprises a surface facing towards the packaging cover plate.

13. A method of manufacturing a display panel, the method comprising:
providing a display substrate, a plurality of connection lines being disposed at intervals on an edge of the display substrate;
forming an insulating layer on a surface of the edge, the insulating layer covering the plurality of connection lines and gaps between adjacent ones of the plurality of connection lines;
removing a portion of the insulating layer on at least a portion of a surface of each of the connection lines to form a plurality of insulating partitions;
placing a packaging cover plate on a surface of the display substrate, the packaging cover plate covering the plurality of insulating partitions, the display substrate, the packaging cover plate and every two adjacent ones of the plurality of insulating partitions defining an accommodation space together, and at least one of the plurality of connection lines being located in one of the accommodation spaces; and
filling conductive fillers in the accommodation spaces, respectively, each of the conductive fillers covering at least a portion of a surface of a corresponding one of the plurality of connection lines.

14. The method of claim 13, further comprising:
forming electrodes on first end surfaces, facing towards an outside of the display panel, of the conductive fillers, and on second end surfaces, facing towards the outside of the display panel, of the connection lines; and
bonding a COF to a side of the electrodes facing away from the connection lines.

15. The method of claim 14, wherein:
each of the electrodes and a corresponding one of the conductive fillers are integrally formed.

16. The method of claim 14, wherein:
the conductive fillers and the electrodes are formed by screen printing or printing.

17. The method of claim 13, wherein:
each of the connection lines has a body, and an end connected to the body and having an outer peripheral surface around a center line of the end, the outer peripheral surface has a first outer peripheral surface portion facing towards the display substrate and a remaining second outer peripheral surface portion, and each of the conductive fillers covers at least a part of the second outer peripheral surface portion of the outer peripheral surface of the end of a corresponding one of the connection lines.

18. The method of claim 17, wherein:
removing the portion of the insulating layer comprises:
removing a portion of the insulating layer covering at least the part of the second outer peripheral surface portion of the outer peripheral surface of the end of each of the connection lines, while retaining a portion of the insulating layer covering the body of each of the connection lines, so as to expose at least the part of the second outer peripheral surface portion of the outer peripheral surface of the end of each of the connection lines, wherein each of the plurality of insulating partitions is constituted by a portion of the insulating layer located between two adjacent ones of the plurality of connection lines in an arrangement direction of the plurality of connection lines.

19. The method of claim 18, wherein:
the part of the second outer peripheral surface portion of the outer peripheral surface of the end of each of the connection lines comprises a surface facing towards the packaging cover plate.

20. A display apparatus comprising the display panel of claim 1.
